(19) United States
(12) Patent Application Publication
(10) Pub. No.: US 2025/0182649 A1
(43) Pub. Date: Jun. 5, 2025

(54) REMOTE FIRST AID TRAINING AND MANIKIN DESIGNS

(71) Applicant: ACADEMIE SAINT-BERNARD INC., Saint-Hyacinthe (CA)

(72) Inventors: Alexandre Grenier, Saint-Hyacinthe (CA); Herve Boudreau, Quebec (CA); Vick Lamarre, Sainte-Brigitte-de-Laval (CA)

(21) Appl. No.: 18/843,448

(22) PCT Filed: Mar. 17, 2023
(86) PCT No.: PCT/CA2023/050350

§ 371 Date: Sep. 3, 2024

(30) Foreign Application Priority Data
Mar. 18, 2022 (CA) 3152663

(51) Int. Cl. G09B 23/28

(52) U.S. Cl. CPC G09B 23/288

(57) ABSTRACT

Head and torso first aid manikins are disclosed, along with variable flow valves for use in a head first aid manikin and first aid training systems and methods. A head manikin comprises an inlet, an outlet distinct from the inlet, and a channel allowing fluid communication between the inlet to the outlet. A variable flow valve is positionable in line with the channel. A torso manikin comprises an inflatable pouch and a fluid pressure sensor configured to detect compressions being applied to the pouch. A first aid training system comprises at least one first aid manikin comprising sensors and a computing device. A first aid training method comprises generating data from a user manipulating a first aid manikin and, in a computing device, receiving the data, comparing the data with first aid reference parameters, and displaying feedback to the user.

### TECHNICAL FIELD

The technical field generally relates to First Aid training, such as CPR training, and manikins designed for such training.

### BACKGROUND

First Aid training, including Cardiopulmonary Resuscitation (CPR) and airway management training, is an important service for a variety of individuals, groups and institutions. Conventionally, First Aid training is conducted in person, and combines theoretical learning with practical exercises performed on manikins. However, with the challenges and limitations notably brought on by the Covid-19 pandemic as well as difficulties for certain individuals such as those living in remote or isolated locations, in-person training has various drawbacks. Remote or on-line training can overcome some issues but itself has various challenges.

Additionally, most manikins use disposable plastic lung bags, which represent an additional expense, generate waste, and make it impossible for a plurality of trainees to practise mouth-to-mouth/nose/mask insufflation on the same manikin safely in contexts where contagious respiratory tract infections are a concern. There is, therefore, a need for a full-featured CPR manikin that does not require the use of lung bags.

### SUMMARY

According to an aspect, there is provided a first aid manikin, comprising: a head comprising: an outer shell defining an inner chamber; an inlet on a front surface of the outer shell; an outlet distinct from the inlet; and a channel within the inner chamber and allowing fluid communication between the inlet to the outlet.

The head can further comprise a one-way valve located in line with the channel and configured to allow fluid flow from the inlet towards the outlet and to block fluid flow towards the inlet.

The head can further comprise a fluid pressure sensor located in the channel.

The head can further comprise a variable flow valve located in line with the channel.

The head can further comprise at least one filtration device located in the channel.

The head can further comprise a flow sensor located in the channel.

The head can further comprise a power supply.

A portion of the head can correspond to a skull that is flexible and extensible with respect to another portion of the head corresponding to a neck.

A portion of the head can correspond to a lower jaw that is slidable along another portion of the head corresponding to a temporal bone.

The head can further comprise a communication device configured to receive readings from the sensors, and to receive and send data to a computing device.

The head can further comprise a controller configured to: receive pressure readings from the fluid pressure sensor; receive flow readings from the flow sensor; and send data to the computing device by the communication device.

The head can further comprise a tilt sensor attached to a rear part of the outer shell, the controller being further configured to receive tilt readings from the tilt sensor.

The head can further comprise a jaw position sensor located in the inner chamber, the controller being further configured to receive jaw position readings from the jaw position sensor.

The channel can comprise an upstream tube extending from a mouth of the head to the one-way valve, a intermediate tube extending from the one-way valve to the variable flow valve, and a downstream tube extending from the variable flow valve to the outlet.

The fluid pressure sensor can be positioned in the intermediate tube.

The flow sensor can be positioned in the downstream tube.

The filtration device can be located in the downstream tube.

The manikin can further comprise a microphone.

The manikin can further comprise a speaker.

The outer shell can be composed of hard plastic.

The front surface of the outer shell can have human face features.

A rear surface of the head can be flat for laying in stable fashion on a floor or ground.

A second rear surface of the head can be flat, wherein the flat rear surface and the second flat rear surface are connected at an acute dihedral angle.

The head can be operably couplable to a torso.

According to another aspect, there is provided a variable flow valve for use in a first aid manikin, the variable flow valve being positionable in line with a channel that provides fluid communication between an inlet and an outlet of the manikin, the variable flow valve comprising: a housing having an inner cavity; an intake provided in the housing; an exhaust provided in the housing and being distal from and in fluid communication with the intake; a gate located within the cavity and being movable between: an open position allowing fluid communication from the intake to the exhaust, a plurality of partially open positions allowing restricted flow fluid communication from the intake to the exhaust, and a closed position blocking fluid communication from the intake to the exhaust; and an actuator configured to move the gate between the open position, the plurality of partially open positions, and the closed position, in response to readings obtained from at least one sensor located on the manikin and generated in response to a user performing first aid manoeuvres on the manikin.

The housing can be configured such that the inner cavity has an upstream region with an outward taper and a downstream region that accommodates the gate and includes the exhaust.

The downstream region can have a spherical shape and the gate has an outer spherical surface that cooperates with inner surfaces of the downstream region to slide thereon.

The gate can have a spherical segment shape.

The exhaust and the intake can be oriented perpendicularly with respect to each other.

The housing can comprise a connector section that defines the intake therein and is connectable to a channel of the manikin.

According to yet another aspect, there is provided a first aid manikin, comprising: a torso comprising: an inflatable pouch, the pouch comprising a flexible wall defining an interior chamber; and a fluid pressure sensor configured to detect compressions being applied to the pouch.

The pouch can further comprise an adult simulation surface on a first side and an infant simulation surface on a second side, in opposed relation to the adult simulation surface.

The fluid pressure sensor can be further configured to detect squeezing being applied to the pouch.

The torso can further comprise an air pump configured to inflate the pouch by forcing air in through an air intake vent.

The torso can further comprise an air exhaust vent configured to deflate the pouch.

The torso can further comprise a solenoid valve attached to the air exhaust vent.

The pouch can further comprise at least two magnets, each magnet being attached to and underneath a surface of the pouch.

The pouch can comprise four magnets.

The manikin can further comprise at least two defibrillation pads, each pad being configured to adhere to a surface of the pouch when applied to said surface, each pad comprising a magnetic field sensor.

The magnetic field sensor can be a Hall effect sensor.

The magnetic field sensor can be a bipolar Hall effect sensor.

The manikin can further comprise a gyroscope sensor.

The manikin can further comprise a microphone.

The manikin can further comprise a speaker.

The manikin can further comprise a vibrating device.

The torso can further comprise a power supply.

The torso can further comprise a communication device configured to receive readings from the sensors, and to receive and send data to a computing device.

The torso can further comprise a controller configured to receive readings from the sensors and send data to the computing device by the communication device.

The flexible wall can have an opening in fluid communication with the interior chamber, and a threaded insert positioned in the opening.

The manikin can further comprise a cylindrical capsule configured to be engaged in the threaded insert.

The capsule can further comprise one or more apparatus selected from the group consisting of: the fluid pressure sensor; the air pump; the air intake vent; the air exhaust vent; the gyroscope sensor; the microphone; the speaker; the vibrating device; the power supply; the communication device; and the controller.

The pouch can be composed of rubber.

The pouch can be composed of silicone rubber.

The torso can be operably couplable to a head.

According to a further aspect, there is provided a first aid training system, comprising: at least one first aid manikin comprising sensors; and a computing device, comprising: a receptor unit for receiving input from the sensors, and a computing unit configured to execute a first aid training program comprising: a training assessment module that compares the input to training parameters, and a display to provide feedback from the assessment module to the trainee.

According to yet a further aspect, there is provided a first aid training method, comprising: generating data from a user manipulating a first aid manikin, the manikin comprising at least sensors, a controller, and at least one of a head and a torso; and in a computing device: receiving the data; comparing the data with first aid reference parameters stored in the computing device; and displaying feedback to the user based on comparison of the data with the first aid training parameters.

The method can comprise that, in response to the user activating the manikin and selecting victim characteristics, a pump forces a volume of air into the torso, the volume of air being computed by the controller based on the victim characteristics.

The method can comprise that, in response to the user moving the head, a head tilt sensor measures a tilt of the head, and the controller computes an airway clearance parameter based on the tilt.

The method can comprise that, in response to the user moving the head, a jaw position sensor measures a jaw position, and the controller computes an airway clearance parameter based on the jaw position.

The method can comprise that, in response to the user moving the head, a head tilt sensor measures a tilt of the head, a jaw position sensor measures a jaw position, and the controller computes an airway clearance parameter based on the tilt and the jaw position.

The method can comprise that, in response to the user forcing air through an inlet in the head, a first fluid pressure sensor measures a first pressure of air, and the controller computes an insufflation force parameter, an insufflation duration parameter and an insufflation count parameter based on the first pressure.

The method can comprise that, in response to the user forcing air through the inlet, the controller computes a flow of air from the first pressure and computes an insufflation volume parameter based on the flow.

The method can comprise that, in response to the user forcing air through the inlet, a flow sensor measures a flow of air being expelled through an outlet in the head, and the controller computes an insufflation volume parameter based on the flow.

The method can comprise that, in response to the user forcing air through the inlet, the controller adjusting a variable flow valve positioned in line with a channel that provides fluid communication between the inlet and the outlet such that it allows a specific flow from the inlet to the outlet, the controller computing the specific flow based on the airway clearance parameter, the insufflation force parameter and the insufflation volume parameter.

The method can comprise that, in response to the user forcing air through the inlet, the pump modifies the volume of air in the torso, a new volume of air being computed by the controller based on the insufflation volume parameter.

The method can comprise that, in response to the user compressing the torso, a second pressure sensor measures a second pressure of gases inside a chamber of the torso, and the controller computes a compression depth parameter, an inter-compression relaxation parameter, a compression frequency parameter and a compression count parameter based on the second pressure.

The method can comprise that, in response to the user squeezing the torso, the second pressure sensor measures a squeezing force applied to the torso, and the controller computes an assessment of consciousness parameter based the squeezing force.

The method can comprise that, in response to the user shouting, a sound sensor measures a sound pressure level, and the controller computes an assessment of consciousness parameter based the sound pressure level.

The method can comprise that, in response to the user squeezing the torso and shouting, the second pressure sensor measures a squeezing force applied to the torso, a sound sensor measures a sound pressure level, and the controller computes an assessment of consciousness parameter based the squeezing force and on the sound pressure level.

The method can comprise that, in response to the user thrusting the torso while the torso is in a airway obstruction treatment, the second pressure sensor measures a thrusting pressure applied to the torso, and the controller computes a thrust force parameter based on the thrusting pressure.

The method can comprise that, in response to the user slapping a back surface of the torso while the torso is in the airway obstruction treatment, the second pressure sensor measures a slapping pressure applied to the torso, and the controller computes a slap force parameter based on the slapping pressure.

The method can comprise that, in response to the user applying a defibrillation pad to a surface of the torso, a magnetic field sensor measures a magnetic field strength, and the controller computes a pad positioning parameter based on the magnetic field strength.

According to another aspect, there is provided a first aid manikin, system and/or method as described above, further comprising one or more features as claimed and/or described and/or illustrated herein.

### BRIEF DESCRIPTION OF THE DRAWINGS

FIG. 1A is a sectional view of a head manikin according to an embodiment.

FIG. 1B is a sectional view of a head manikin according to an alternative embodiment.

FIG. 2 is a sectional view of a partial flow valve for a head manikin according to an embodiment.

FIG. 3 is an elevation view of a torso manikin according to an embodiment.

FIGS. 4A and 4B provide two plan views of a torso manikin according to an embodiment.

FIG. 5 is an elevation view of a defibrillation pad according to an embodiment.

FIG. 6 is a sectional view of a capsule for a torso manikin according to an embodiment.

FIG. 7 is a diagram illustrating a system for First Aid training and assessment using a head and a torso manikin.

FIG. 8 is a flowchart illustrating a general method for First Aid training and certification.

FIG. 9 is a flowchart illustrating a method for First Aid training and assessment using a head and a torso manikin.

### DETAILED DESCRIPTION

The present description relates to systems, methods and manikin designs for CPR training, airway management training and other types of training where manikins could be used. The manikins can include various features that facilitate strong training performance along with efficient manufacturing and delivery to remote training locations. The training system can include the use of a computing device that is configured to receive data generated by the trainee's manipulation of the manikin, compare the data against CPR and airway management reference parameters, and display feedback to the trainee to aid in the training and certification. The computing device and the manikin can have certain integration features to provide feedback to the trainee and/or simulate certain physiological events that could occur. Various aspects and optional embodiments of the technology will be described in further detail below.

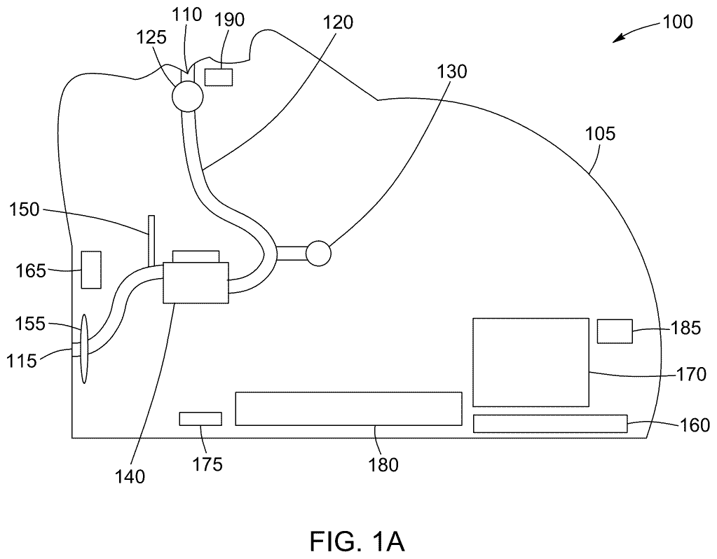

With reference to FIG. 1A, an example embodiment of a head manikin 100 suitable for use in First Aid training and assessment is shown. The head manikin 100 can have a flexible neck and temporomandibular joint, allowing a trainee to simulate performing a head tilt and/or jaw thrust manoeuvres, and an air channel 120 can be configured such that air forced by a trainee through the inlet 110 is evacuated through an outlet 115. Situations in which the airway is blocked or the lungs are full can be simulated using a variable flow valve 140.

Furthermore, the head manikin 100 can include an outer shell 105. The outer shell 105 can have a shape and decorations meant to imitate the classical anatomical representations of a human head, including for instance the forehead, the superciliary arches, the eyes, the nose, the cheeks, the mouth, the jaws and the ears. The same outer shell 105 can be used to represent the anatomical landmarks of, for instance, a 40-year-old adult at a scale of 1:1, a 10-year-old child at a scale of 1:1.2, and a 10-month infant at a scale of 1:1.5. Other scale ratios and human ages or phenotypes can also be provided by the outer shell. The back of the outer shell 105 can be substantially flat in order to avoid accidental movement of the manikin during use by a trainee while, for instance, the manikin is laid out on a table or on a floor. The outer shell 105 can be composed of moulded plastic, for instance rigid plastic such as polypropylene, high-density polyethylene or polyethylene terephthalate, flexible plastic such as polyvinyl chloride, thermoplastic polyurethane, or synthetic or natural rubber. It can be made of multiple pieces assembled such that certain points are flexible, such as the neck (e.g., making its flexion, extension and/or rotation possible, e.g., to simulate a head tilt manoeuvre) and/or the temporomandibular joints (e.g., making the advancement and the retraction of the mandible possible, e.g., to simulate a jaw thrust manoeuvre). Nonetheless, the outer shell 105 in the area around the mouth and nose of the head manikin 100 ideally comprise only one piece in order to allow a hermetic seal when practising mouth-to-mask or bag valve mask insufflation.

The outer shell 105 can be opened in at least one inlet 110 in order for a trainee to be able to practise administering artificial ventilation. The inlet 110 can for instance be located inside a mouth feature of the outer shell 105, substantially corresponding to the location of the mouth opening in a human head. It is appreciated that more than one inlet 110 can exist. For instance, there can be two additional inlets under a nose feature of the outer shell 105, substantially corresponding to the location of the nostrils in a human head, making it possible for the trainee to practise administering mouth-to-nose and/or mouth-to-mouth and nose insufflation.

The outer shell can additionally be opened in at least one outlet 115. The inlet and outlet can be connected by a channel 120, such that fluid forced through the inlet 110 is evacuated through the outlet 115 when the channel is in an open configuration. A one-way valve 125 can be installed within the channel 120, such that fluid can flow along the channel 120 from the inlet 110 towards the outlet 115 but cannot backflow up the channel 120 towards the inlet 110. In some embodiments, the one-way valve can be a check valve. The check valve can have various constructions suitable for incorporation into the channel 120.

A fluid pressure sensor 130 can be installed within the channel 120 in order, for instance, to measure the pressure of air insufflated by a trainee through the inlet 110. It can be appreciated that the pressure sensor 130 can also be installed within a secondary channel in fluid communication with the channel 120. The pressure sensor 130 can for instance be a piezoresistive pressure transducer, such as a Honeywell MPR, an Omcron 2SMPP or a Metrodyne MPS sensor, transmitting an electric signal proportional to a change in the conductance of a sensing element, such as a metal or a silicon gauge caused by a pressure change, the signal being translatable to an absolute or relative pressure that can for instance be expressed in newtons per square metre (N/m², or Pa), in dynes per square centimetre (dyn/cm², or Ba), in pound of force per square inch (lbf/in², or psi) or in centimetres of water (cmH₂O). Various pressure sensor constructions and methods can be used.

A variable pressure valve 140 can be installed within the channel 120 in order, for instance, to control the fluid flow allowed to transit from an upstream side to a downstream side of the channel 120 with respect to the variable pressure valve 140.

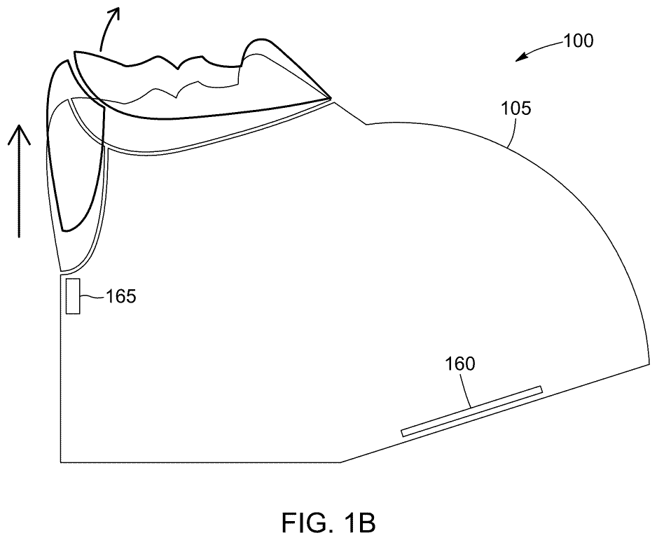

With reference to FIG. 2, an example embodiment of a variable pressure valve 140 suitable for use in a head CPR manikin 100 is shown. The variable pressure valve 140 can include a housing 141 having an inner cavity 143 that provides fluid communication between an intake 145 and an exhaust 147. The housing 141 can for instance be 3D-printed and composed, e.g., of polylactic acid or polyethylene terephthalate glycol-modified, or be injection-moulded and composed of e.g., acrylonitrile butadiene styrene or propylene. The housing 141 can be barbed at a position around the intake 145 and/or the exhaust 147 to facilitate fitting within in the channel 120, although various alternative connection methods are possible.

A gate 149 can be installed at a position aligned on the cavity 143, such that the gate is movable from an open position wherein it does not physically block the fluid flow in the cavity 143, through a plurality of partially open positions, to a closed position wherein it physically blocks the fluid flow in the cavity 143. An actuator can be installed and coupled to the gate 149 so as to cause it to move from one position to another. The actuator can for instance be a linear servomotor directly actuating the gate 149, a rotatory servomotor or a stepper motor actuating a threaded rod actuating the gate 149 with or without gearing. In some embodiments, the gate 149 can comprise a threaded surface configured, such that the gate 149 can be actuated by a rotary servomotor or by a stepper motor without a threaded rod, with or without gearing. It can be appreciated that a function can be defined to map a starting position of the gate 149 and an actuator movement to a level of flow rate restriction. In such a function, the position of the gate 149 can for instance be expressed as a fraction of the cavity 143 cross-sectional area not being physically blocked by the gate 149, and the level of flow rate restriction can for instance be expressed as a fraction of the flow rate of the cavity 143 when the gate 149 is in an open position.

In some embodiments, the cavity 143 can have an upstream region having a substantially rectangular parallelepipedal shape and opening in a downstream region having a substantially spherical shape, such that the upstream section has an opening into the downstream section in a substantially spherical rectangular shape. In these embodiments, the intake 145 can be located at an extremity of the upstream region and the exhaust 147 can be located at a position of the downstream region such that there is an angle of, for instance, 90°, 135° or 180°, or any angle in between such angle values, between the intake 145 and the exhaust 147. The gate 149 can have a spherical surface that can slide on the inner surfaces of the downstream region such that, when in a closed position, the gate 149 blocks the opening of the upstream section. The gate 149 can for instance be substantially shaped as a segment or as a sector of a sphere having the same radius as the downstream region. In preferred embodiments, the function mapping a starting position of the gate 149 and an actuator movement to a level of flow rate restriction can be a linear function.

Referring once more to FIG. 1A, a flow sensor 150 can be installed within the channel 120 in order to measure the flow rate of air moving towards the exhaust. It can be appreciated that the flow rate of air moving towards the exhaust at the position of the flow sensor 150 can alternatively or additionally be computed from the readings of the pressure sensor 130 and the position of the gate 149 of the variable flow valve, for example using the Hagen-Poiseuille law.

A filtration device 155 can be installed within the channel 120 in order to prevent the spreading of airborne particulates and organisms to the surrounding environment, for instance when a trainee is practising mouth-to-mouth, mouth-to-mask, mouth-to-nose or mouth-to-mouth and nose insufflation. The filtration device 155 can for instance comprise a mesh filter and/or a fibrous filter, including charcoal-activated filters and/or uncertified, high-efficiency or ultra-low particulate air filters, or a combination of more than one filter of the same or different types. It can be appreciated that filters used in the filtration device 155 can be permanent or replaceable filters. In some embodiments, the filtration device 155 can be positioned over the exhaust 115. In some embodiments, one or more filtration devices can alternatively or additionally be installed over the intake 110 and/or in the channel 120 at a position close to the intake 110.

It can be appreciated that the channel 120 can for instance comprise a plurality of tubes. In some embodiments, an upstream tube can be attached to the inlet 110 at one end and to the intake of the one-way valve 125 at the other end; an intermediary tube can be attached to the exhaust of the one-way valve 125 at one end and to the intake 145 of the variable flow valve 140 at the other end; and a downstream tube can be attached to the exhaust 147 of the variable flow valve 140 at one end and to outlet 115 at the other end. Other arrangements of tube sections are also possible depending on the internal channel design. Each tube can be made from a flexible or a rigid material, for instance silicone, polyurethane, polyvinyl chloride or flexible or rigid aluminium. All tubes can but need not necessarily be made of the same material. In some embodiments, the pressure sensor 130 can be installed in the intermediary tube, and the flow sensor 150 and the filtration device 155 can be installed in the downstream tube.

Furthermore, a tilt sensor 160 can be installed inside the hard shell 105, for instance in a position adjacent to the rear surface thereof, in order to detect whether a head tilt manoeuvre was performed by a trainee using the head manikin 100. In some embodiments, the tilt sensor 160 can comprise a gyroscope and/or an analog rotation sensor configured to detect changes in the orientation of the rear surface with respect to the horizontal plan. In some alternative embodiments, as illustrated in FIG. 1B, the rear surface of the hard shell 105 can comprise two flat back surfaces meeting at a straight intersection line and having between them an acute dihedral angle, for instance, 5°, 10° or 15° or any angle in between such angle values. The two back surfaces can be configured such that, when the head manikin 100 is first laid on a plane, e.g., the ground, the first back surface comes naturally in contact with the plane, and when a trainee performs a head tilt manoeuvre, the head tips and the second back surface comes in contact with the plane. In these embodiments, the tilt sensor 160 can comprise a contactor configured to detect whether the second back surface is in contact with the plane. In such configurations, the overall head manikin 100 has a mechanical energy source, including for instance a weight distribution and/or a spring, that causes the first back surface to naturally contact a horizontal plane when the head manikin is placed on it, and a certain tilting force is required to move the head manikin 100 to a tilted position in which the second back surface comes into contact with the horizontal plane.

A jaw position sensor 165 can be installed inside the hard shell 105, for instance underneath the flexible temporomandibular joint of the head manikin 100, in order to detect whether a jaw thrust manoeuvre is actively being performed by a trainee using the head manikin 100. The jaw position sensor 165 can for instance comprise a contactor configured to detect whether the position corresponding to the mandibular condyle of a human skull is adjacent to the position corresponding to the mandibular fossa of the temporal bone of a human skull. It can be appreciated that other contactor placements can be conductive to detecting whether a jaw thrust is being performed. The jaw position sensor 165 can alternatively or additionally comprise a slide position sensor, for instance an electronic potentiometer analog slide position sensor, e.g., an AlsRobotBase RB-02S071A or a DFRobot DFR0053 sensor, transmitting an electric signal proportional to the position of a slider along a slide wire. The slide wire can for instance be attached to a position corresponding to the temporal bone and the slider be attached to a position corresponding to the mandibular condyle.

A power supply 170 can be installed inside the hard shell 105, in order to provide power for instance to the sensors 130, 150, 160 and 165, to the actuator of the gate 149 of the variable flow valve 140, to the communication device 175 and/or to the controller 180. A single power supply can be provided for all units inside the head manikin 100 requiring power, or multiple power supplies can be used for different units. While the power supply 170 can be installed in a position near the rear surface of the hard shell 105 to improve the stability of the head manikin 100, it is appreciated that other locations inside or outside the hard shell 105 are also possible. The power supply 170 can for instance comprise an energy storage device such as a rechargeable or non-rechargeable battery, including for instance alkaline, nickel-metal and lithium-ion batteries, and/or an AC/DC adaptor usable with an external power source, for instance a computing device, the power grid or an engine generator. In some embodiments having an internal power supply 170, the power supply 170 can be removable and accessible through an opening in the outer shell 105 for inspection, recharging and/or replacement. In some embodiments, an internal rechargeable power supply 170 can be recharged internally by inserting a charging cable through a power inlet or a communication and power supply port, including for instance an IEEE 1394 port, a USB or a Thunderbolt port, installed in the outer shell 105.

A communication device 175 can be installed inside the hard shell 105, in order to allow for communication between a controller 180 and the sensors 130, 150, 160 and 165, the actuator of the gate 149 of the variable flow valve 140, and/or an external computing device. The communication device 175 can for instance comprise an Espressif Systems ESP32 microcontroller. In some embodiments, the functions of the communication device 175 can be performed by a plurality of devices of the same or different types, including for instance Bluetooth, Wi-Fi, Ethernet, IEEE 1394, USB and Thunderbolt adaptors. In embodiments using for instance IEEE 1394, USB and/or Thunderbolt both as power supplies 170 and as communication devices 175, it can be appreciated that a single IEEE 1394, USB and/or Thunderbolt port can optionally be used for both communication and power supply.

A controller 180 can be installed inside the hard shell 105, in order to perform computations based on readings received from the sensors 130, 150, 160 and 165, to control the actuator of the gate 149 of the variable flow valve 140, and to control sending data to one or more external computing devices. The controller 180 can for instance comprise one or many purpose-made and/or general-purpose printed circuit boards, including single-board computers such as Raspberry Pi and microcontroller boards such as Arduino, or embedded systems. The controller 180 can have access to a system for computing elapsed time, for instance a hardware or software real-time clock. It is appreciated that some or all of the functions of the controller 180 can be delegated to one or more external computing device, including for instance a desktop or laptop computer, a tablet, a smartphone and/or a personal digital assistant.

A sound pressure sensor and/or a microphone 185 can further be installed inside the hard shell 105, for instance at a position near the ears, in order to detect and/or process speech by the trainee, for instance using an existing automatic speech recognition framework that can be executed to convert the words spoken by the trainee to text.

A speaker 190 can further be installed inside the hard shell 105, for instance at a position near the mouth, in order to emit sounds including, for instance, speech by the victim, coughing sounds (e.g., dry or productive cough), respiratory sounds (e.g., wheezing, rhonchi, stridor or crackles), and/or emesis sounds. The training program can be configured such that the trainee is asked to adapt assessment and actions depending on different sounds emitted by the manikin.

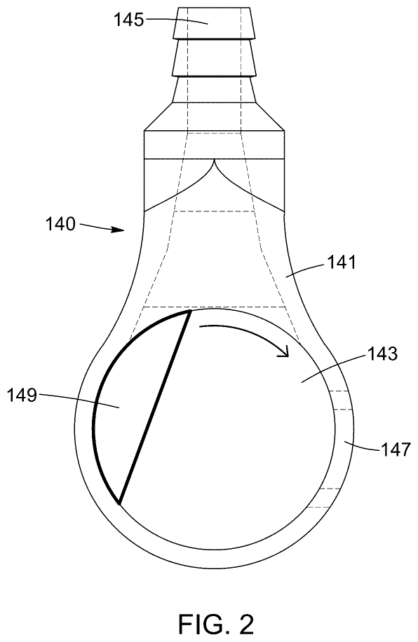

With reference to FIG. 3, an example embodiment of a torso manikin 200 suitable for use in First Aid training and assessment is shown. Described broadly, the torso manikin can comprise an inflatable pouch 201 with flexible walls defining an inner chamber 205 that can be squeezed or compressed to simulate First Aid manoeuvres. In some embodiments, the torso manikin 200 can be used to simulate both manoeuvres on an adult or child by using an adult surface 210 and on an infant by using an infant surface 215. The air volume and pressure in the pouch 201 can be controlled both by a trainee's manoeuvres and by an air pump 251, and can be measured by a pressure sensor 257, both of which can be placed in a capsule 250 that is connected to the inflatable pouch 201. In some embodiments, the inflatable pouch 201 can be externally reminiscent of a conventional rectangular hot water bottle, and the capsule 250 can be installed in a manner similar as would a hot water bottle stopper.

The torso manikin can be mainly defined by walls of a pouch 201 surrounding an airtight chamber 205. The walls can be made of an airtight material with a degree of elasticity, for instance an airtight material having a Young's modulus below 1 GPa, including natural or synthetic rubber, silicone rubber and/or low-density polyethylene. One wall of the pouch 201, defining the adult surface 210, can have decorations meant to imitate the classical anatomical representations of a human upper torso, including for instance the neck, the clavicles, the sternum, the nipples and the lower limit of the rib cage. The adult surface 210 can be used to represent the anatomical landmarks of, for instance, a 40-year-old adult at a scale of 0.85:1, a 10-year-old child at a scale of 1:1. Another wall of the pouch 201, defining the infant surface 215, parallel and opposed to the adult surface 210 across the chamber 205, can have decorations meant to imitate the classical anatomical representations of a human infant torso, including for instance the neck, the shoulders, the humeri, the armpits, the sternum, the nipples, the navel and the hips. The infant surface 215 can be used to represent the anatomical landmarks of, for instance, a 10-month-old infant at a scale of 1:1.

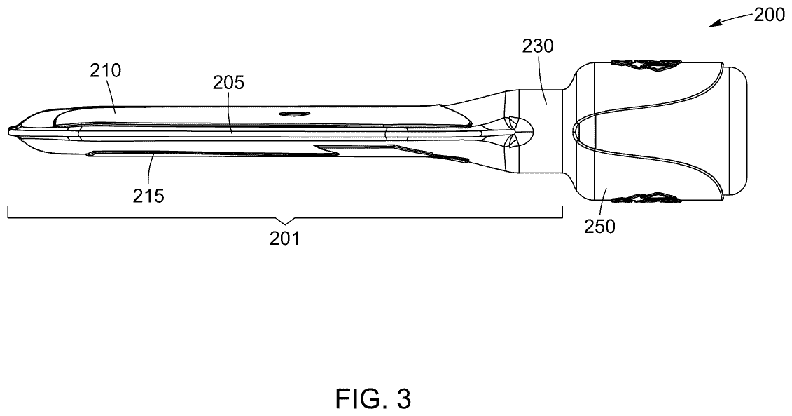

Referring to FIGS. 4A and 4B, the adult surface 210 and the infant surface 215 can be integrally moulded to the main body of the inflatable pouch or can be formed by adhering, permanently or removably, a flat overlay onto respective external surfaces of the pouch. The adult surface 210 and the infant surface 215 can be provided with different shapes and sizes to clearly distinguish between the two. The adult and infant surfaces 210, 215 can be the same or different compared to each other and/or compared to the surrounding portions of the pouch in terms of colour, texture, rigidity, flexibility, thickness and/or other characteristics.

In one example, the adult surface 210 includes edges that are raised, indented or flat and include an upper curvilinear edge in spaced-apart relation with the neck of the pouch and a lower curvilinear edge in spaced-apart relation with the lower end of the pouch. The side edges of the adult surface 210 can extend respectively to the two later sides of the pouch. The upper edge can have an arcuate shape reminiscent of the clavicle, while the lower edge can have a bell-curve type shape reminiscent of the costal arch, although various shapes and configurations are possible. FIG. 4 shows an example where the adult surface has no arm or neck portions, which can help clearly distinguish it from the infant surface when the latter includes such portions. In one example, the infant surface 215 has an edge contour that is entirely spaced-away from the outer edge part of the pouch. The edge contour of the infant surface 215 can be shaped to include portions that are reminiscent of part of the neck, the upper arms, and the torso including the chest and abdomen of an infant.

With reference to FIG. 4, magnets 220a, 220b and 220c can be installed in the chamber 205 underneath adult surface 210, and magnet 220d can be installed in the chamber 205 underneath infant surface 215, in order to assess the capability of the trainee to apply defibrillation pads of an automated external defibrillator (AED) at the correct positions on the torso manikin 200. The magnets can for instance be fastened to the underside of or embedded in the flexible walls with a glue appropriate for the materials in which the magnets and the flexible walls are composed, including for instance a cyanoacrylate based adhesive or an epoxy adhesive. Other connection mechanisms can also be used. Magnets can be installed at the locations where the pads should be applied in adults and children according to AED usage recommendations. For instance, magnet 220a can be installed underneath a position of the adult surface 210 corresponding to an area under the right clavicle of an adult human anterior torso area, magnet 220b underneath a position of the adult surface 210 corresponding to an area under the left flank of an adult human anterior torso area, magnet 220c underneath a position of the adult surface 210 corresponding to the centre of the sternum of a child human, and magnet 220d underneath a position of the infant surface 215 corresponding a position between the shoulder plates of a child human back. In preferred embodiments, magnets 220a, 220b, 220c and 220d are installed such that each magnet points a specific magnetic pole towards the exterior of the pouch 201, such that magnets corresponding to the locations where the pads should be applied in adults according to AED usage recommendations have one polarity, for instance north, while magnets corresponding to the locations where the pads should be applied in children according to AED usage recommendations have a different polarity, for instance south. In these embodiments, therefore, magnets 220a and 220b can point the same pole, for instance their north pole, towards the exterior, and magnets 220c and 220d can point the opposite pole, for instance their south pole, towards the exterior.

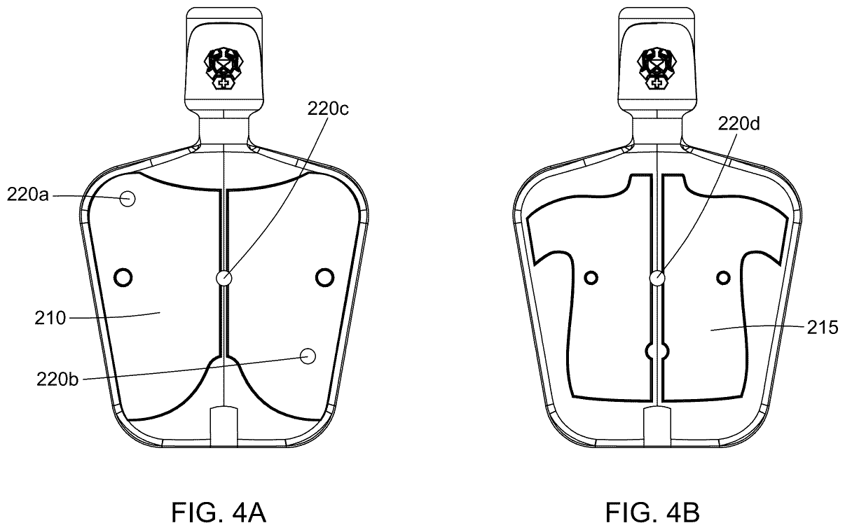

With reference to FIG. 5, two defibrillation pads 240 can be provided, in order to cooperate with the magnets 220a, 220b, 220c and 220d to assess the capability of a trainee to apply the defibrillation pads of an automated external defibrillator (AED) at the correct position on the torso manikin 200. The defibrillation pad 240 can comprise an adhesive strip 241 configured to allow the pad to temporarily attach to a surface 210 or 215 of the torso manikin 200. The adhesive strip 241 can for instance be coated with a gel that allows it to detachably adhere to the surface, or can include a metal plate or a magnet that allows it to adhere to the surface through attraction to the magnets installed underneath said surface. The defibrillation pad 240 can further comprise a magnetic field sensor 243 configured to detect the magnetic field generated by a magnet installed underneath the position of the surface to which the pad 240 is attached. In preferred embodiments, the magnetic field sensor 243 is further configured to detect the polarity of the magnetic field. In some embodiments, the magnetic field sensor 243 is a bipolar Hall effect sensor such as Texas Instrument DRV5053 a Honeywell SS41 sensor, transmitting an electric signal when magnetic flux lines exert a force on current passing through a piece of semiconductor material, the signal being translatable to a magnetic field strength that can for instance be expressed in weber per square metre (Wb/m², or T).

The defibrillation pad 240 can further comprise a circuit board 245 and a connector 247. The circuit board 245 can comprise one or many purpose-made and/or general-purpose printed circuit boards that are configured to prepare readings obtained by the magnetic field sensor 243 for communication to a device external to the pad 240 by means of the connector 247. The connector 247 can for instance comprise an IEEE 1394, USB, Thunderbolt and/or 3.5 mm TRRS adaptor, including an appropriate port to connect a transmission cable, for instance between the pad 240 and a corresponding port on the torso manikin 200, e.g., within the capsule 250, and/or an external computing device such as a tablet, smartphone or personal digital assistant. It can be appreciated that the connector 247 can additionally or alternatively comprise an adaptor for radio communication, for instance a Bluetooth or Wi-Fi adaptor, such that the pad 240 can be connected wirelessly to the torso manikin 200 and/or an external computing device. Referring back to FIG. 3, in preferred embodiments, the flexible wall of the inflatable pouch 201 can have an opening, for instance at a position corresponding to the neck feature of the pouch 201, in fluid communication with the interior chamber 205, and a threaded insert 230 installed in the opening such that airtightness is maintained, for instance by moulding-in the threaded insert 230. The threaded insert 230 can be made of a material different than the flexible walls of the inflatable pouch 201, for instance of a metal such as brass, stainless steel or aluminium, or of a plastic such as nylon, acrylonitrile butadiene styrene or polytetrafluoroethylene. In these embodiments, a capsule 250 can be provided. The capsule 250 can have a threaded cylindrical part configured to engage with the threaded insert 230, so that the capsule 250 becomes hermetically attached to the inflatable pouch 201 and the interior of the capsule 250 and/or tubes located inside the capsule 250 become in fluid communication with the chamber 205. The capsule 250 can for instance be 3D-printed and composed, e.g., of polylactic acid or polyethylene terephthalate glycol-modified, or be injection-moulded and composed e.g., of acrylonitrile butadiene styrene or propylene. In preferred embodiments, the capsule 250 is provided with a cover which, when attached to the capsule 250, makes it water-resistant.

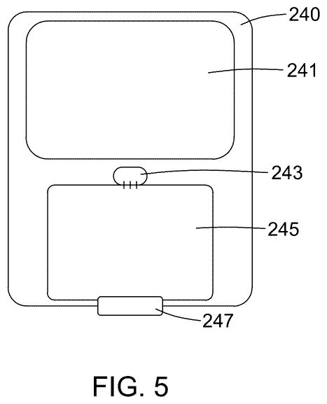

Referring to FIG. 6, the capsule 250 can comprise an air pump 251, for instance an air compressor, configured to force air into the inflatable pouch 201 through an intake vent 253, in order for instance to inflate the pouch 201 to a realistic pressure upon starting a practice session and to inflate the pouch 201 to provide visual feedback to a trainee performing insufflation. The capsule 250 can also comprise an exhaust vent 255 configured to let air out of the inflatable pouch 201. In some embodiments, the exhaust vent can be attached to a solenoid valve 256, for instance a normally-closed electric solenoid vent valve, to precisely control the pressure of air in the pouch 201. The capsule 250 can further comprise a fluid pressure sensor 257 configured to measure the air pressure inside the torso manikin 200, in order to determine whether the trainee is squeezing or compressing the pouch 201. It can be appreciated that the pressure sensor 257 can function substantially in the same way as the head manikin pressure sensor 130 or in a different way. In some embodiments, the capsule 250 can be airtight and in fluid communication with the chamber 205 of the inflatable pouch 201, such that the pressure in the capsule 250 is equal to the pressure in the chamber 205. In these embodiments, the air pump 251, the solenoid valve 256 and the fluid pressure sensor 257 can operate directly on air inside the capsule 250. In alternative embodiments, The air pump 251, the solenoid valve 256 and the fluid pressure sensor 257 can be connected to the chamber 205 through one or more tubes. In these embodiments, it is appreciated that the air pump 251, the solenoid valve 256 and the fluid pressure sensor 257 can be connected to the chamber 205 of the inflatable pouch 201 in a substantially similar manner as the non-invasive blood pressure module is connected to the inflatable cuff in an electronic sphygmomanometer. Each tube in the capsule 250 can be made from a flexible or a rigid material, for instance silicone, polyurethane, polyvinyl chloride or flexible or rigid aluminium. All tubes can but need not necessarily be made of the same material.

The capsule 250 can further comprise a power supply 259, in order to provide power for instance to the pump 251, the pressure sensor 257, the communication device 261, the controller 263, the LED indicators 267, the solenoid valve 256, the gyroscope 273 and/or, through a communication and power cable, to the circuit magnetic field sensors 243 and the circuit board 245 of the defibrillation pads 240. The power supply 259 can be configured in the same way as the power supply 170 of the head manikin 100 or in a different way. A single power supply can be provided for all units inside the torso manikin 200 and capsule 250 requiring power, or multiple power supplies can be used for different units.

The capsule 250 can further comprise a communication device 261, in order to allow for communication between a controller 263 and the pump 251, the solenoid valve 256, the pressure sensor 257, the gyroscope 273, an external computing device, and/or, through communication and power cables, the circuit boards 245 and/or the magnetic field sensors 243 of the defibrillation pads 240. In some embodiments, the functions of the communication device 261 can be performed by a plurality of devices of the same or different types, including for instance Bluetooth, Wi-Fi, Ethernet, IEEE 1394, USB and Thunderbolt adaptors. In embodiments using for instance IEEE 1394, USB and/or Thunderbolt both as power supplies 259 and as communication devices 261, it can be appreciated that a single IEEE 1394, USB and/or Thunderbolt port can optionally be used for both communication and power supply.

The capsule 250 can further comprise a controller 263, in order to perform computations based on readings received from the sensors 243, 257 and/or 273, to control the pump 251 and the solenoid valve 256, and to control sending data to external computing devices. The controller 263 can be configured in the same way or in a different way as the controller 180 of the head manikin 100. The controller 263 can have access to a means for computing elapsed time. It is appreciated that some or all of the functions of the controller 263 can be delegated to one or more external computing device.

The capsule 250 can further comprise a button 265 or switch, operable to power up the torso manikin 200, LED indicators 267, configured to indicate that the torso manikin 200 is powered up and/or is ready for training, one or more connector 269 configured for use with the communication device 261, and one or more card slots 271 configured to allow for the connection of external peripheral devices, for instance using a PCMCIA or an ExpressCard interface.

The capsule can further comprise a gyroscope 273, in order to detect the orientation of the torso manikin 200. As an example, the gyroscope 273 can for instance be used to determine whether the torso manikin 200 is being held in a vertical position or is laying in a horizontal position and, in the latter case, which of the adult 210 or infant 215 surface is facing upward.

The capsule can further comprise a sound pressure sensor and/or a microphone 275, in order to detect and/or process speech by the trainee, for instance using an existing automatic speech recognition framework that can be executed to convert the words spoken by the trainee to text.

The capsule can further comprise a speaker 277, in order to emit sounds including, for instance, auscultatory sounds from the respiratory, cardiac and/or digestive system that the trainee would hear, e.g., through a stethoscope, if they auscultated a victim.

The capsule can further comprise a vibrating device 279, in order to simulate a pulse, for instance a carotid pulse perceivable by the trainee at a position corresponding to the neck feature of the pouch 201. The vibrating device 279 can for instance comprise one or more eccentric rotating mass motors, piezoelectric vibrating motors and/or linear resonant actuators. It can be appreciated that the pump 251, the intake vent 253, the exhaust vent 255, the pressure sensor 257, the power supply 259, the communication device 261, the controller 263, the button 265, the LED indicators 267, the connector 269, the card slot 271, the gyroscope 273, the microphone 275, the speaker 277 and the vibrating device 279 need not be in a capsule 250 and can be located at a different location internal or external to the inflatable pouch 201 without substantially modifying the configuration of the embodiments described herein. Certain components, for instance the microphone 275, the speaker 277 and the vibrating device 279, can for instance be embedded into an external printed circuit board that is configured to be insertable into the card slot 271.

In some embodiments, only one of a head manikin 100 and a torso manikin 200 can be provided, for instance in order to allow a trainee to practise either (i) airway management and/or ventilation, or (ii) AED use and/or chest compressions. In other embodiments, both manikin components 100 and 200 are provided and cooperate together, in order to allow a trainee to practise a complete life support and CPR program. In these embodiments, the head manikin 100 and the torso manikin 200 can be operably coupled. For instance, they can be connected to one another using a cable capable of transporting data and/or power, including for instance an IEEE 1394, USB, Thunderbolt, Ethernet or DC power cable, directly or through an external computing or networking device. They can alternatively or additionally be connected to one another through a radio link, including for instance a Bluetooth or a Wi-Fi link, directly or through an external computing device or networking device. In some embodiments, only one of the power supply 170 of the head manikin 100 and the power supply 259 of the torso manikin comprises an energy storage device, both manikins 100 and 200 being connected by a cable capable of transporting power from the power supply 170 or 259 comprising an energy storage device to the other one. In some embodiments, only one of the head manikin controller 180 and the torso manikin controller 263 is provided, in order for instance to delegate the functions of the head manikin controller 180 to the torso manikin controller 263 or vice versa. In other words, a single controller can be provided for controlling both the head manikin and torso. It can be appreciated that, when the head manikin 100 and the torso manikin 200 are thus operatively coupled, any number of functions of one can be delegated to the other. In some embodiments, the head manikin 100 and the torso manikin 200 can alternatively or additionally be fastened together, for instance through a buckle clip attached to a position corresponding to a neck feature of the head manikin 100 and to the capsule 250, as to have a shape and decorations meant to imitate the classical anatomical representations of a human upper body. Various mechanical connection methods can be used to couple the head manikin and torso together.

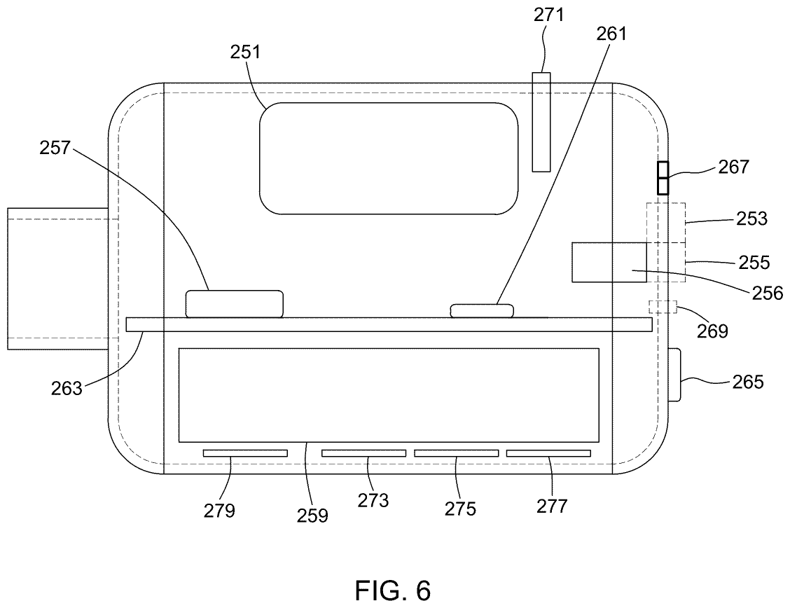

With reference to FIG. 7, a First Aid, CPR, airway management and ventilation training system 300 is shown according to an embodiment. Broadly described, a trainee in a training environment 310 can use a computing device 312 to communicate with a server 362 in a school environment 360 in order to receive didactic presentations and participate in evaluations. Additionally, the trainee can use a head manikin 100 and/or a torso manikin 200, for example as described above, to participate in practical sessions and evaluations.

The training environment 310 can encompass for instance a room in an office building, a school, a hospital, a house or a flat, and a computing device 312 can be provided in the training environment 310. The computing device 312 can comprise any device operable by a trainee, including for instance a desktop computer, a laptop computer, a tablet, a smartphone and/or a personal digital assistant, that is configured to execute a training application, for instance through a smartphone app 314. It can be appreciated that, alternatively or additionally, the computing device 312 can be configured to execute a web application that communicates with a server 362 in a school environment 360 via any suitable protocol such as HTTP and receive computer code from the server 362 that can be used to generate a graphical user interface.

The training environment 310 can further comprise one or more CPR manikins and associated devices, including for instance the head manikin 100, the torso manikin 200 and two defibrillation pads 240 described hereinbefore. In the example embodiment, the defibrillation pads can be connected to the torso manikin 200, both the head 100 and the torso 200 being in turn connected to the computing device 312. These connections can be established through a cable or wirelessly, as described hereinbefore. Either or both the head 100 and the torso 200 manikin can comprise a microphone 185 and/or 275, and/or a speaker 190 and/or 277. It can be appreciated that the computing device 312 can also comprise a microphone and/or a speaker, and that any of these microphones and/or speakers can be used in the system 300 and in the methods described hereinafter in substantially the same way.

Responsive to the trainee practising life support manoeuvres using the manikins 100 and/or 200, the manikin controllers 180 and 263 and/or the computing device 312 can compute a number of parameters 320 reflecting the performance of the trainee. The computing device 312 can be connected, for instance through a network communication link, to a server 362 located in a school environment 360. The server 362 can have access to a set of reference parameters 364, which can be saved in a storage device within or accessible to the server 362. The computing device 312 can send the computed parameters 320 to the server 362 for comparison with the reference parameters 364 in order to compute a scored assessment of the performance of the trainee. The computed parameters 320 can further be recorded in a performance database 366, which can be saved in a storage device within or accessible to the server 362, for future reference. It can be appreciated that the school environment 360 can implement secure data management practices, for instance by implementing standards such as ISO/IEC 27001, to uphold the confidential nature of data such as that stored in the performance database 366. Moreover, the server 362 can retain and make accessible to the public information about trainees having successfully completed a course and obtained the corresponding certification, including for instance their name, type of certification and a unique number. Although the term server is used, it is appreciated that the server 362 can correspond to a plurality of servers, each of which implements all or a subset of the functionalities of the server, and/or which share the processing load among themselves.

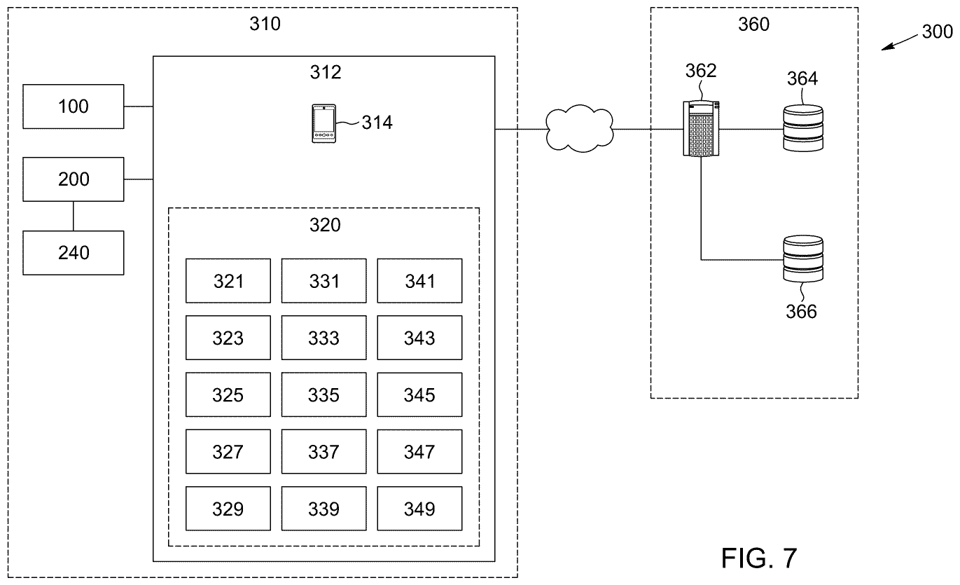

With reference to FIG. 8, the training system 300 can be used to perform an example general training and certification method 400. Broadly described, the method 400 makes it possible for a trainee to register in and follow a course including, e.g., CPR training, such as a Basic Life Support course, and obtain a corresponding certification.

Once the trainee is registered in the course, as a first step 410, they may first be required to attend didactic presentations in the training environment 310 to learn the theory behind life support, CPR, airway management and ventilation, for instance via the smartphone app 314 or another training application executed on the computing device 312. The didactic presentations can include any material necessary for the trainee's learning, comprising for instance charts, flowcharts, texts, illustrations, photos, animated images, videos and/or audio tracks. The trainee can be required to confirm that they have perused and understood each didactic presentation, for instance by clicking on a button of the smartphone 314 that acts as a type of digital signature. This step may be referred to as the presentation step 410.

Once the trainee has confirmed perusing all the didactic presentations, as a next step 420, they may be required to take one or more theoretical evaluations validating their understanding of the theory. The theoretical evaluation may comprise for instance a multiple-choice questionnaire, a long essay questionnaire, a short answer questionnaire and/or an association questionnaire. The trainee may need to obtain a score above a minimum passing score set by an instructor or the system. The trainee may have the opportunity to retake the evaluation until the minimum passing grade is reached. This step may be referred to as the theoretical evaluation step 420.

Once the trainee has successfully completed the one or more theoretical evaluations, as a next step 430, they may partake in practice sessions, for instance following a life support, CPR, airway management and ventilation program and applying manoeuvres on manikins and associated devices, including for instance the head manikin 100, the torso manikin 200 and/or the defibrillation pads 240 described hereinbefore. During each practice session, a number of parameters 320 can be computed and stored securely by the server 362 in the school environment 360. The trainee may be required to complete all practice sessions presented to them in their training within a given minimum time period. Depending on the proposed practice session, the trainee may be timed during their activity. The trainee may have a period of time chosen by the instructor to practise the different techniques seen in the training in order to master the techniques being taught. This step may be referred to as the practice step 430.

As a next step 440, the trainee may have to take one or more practical evaluation validating their proficiency in following the life support, CPR, airway management and ventilation program and applying manoeuvres on CPR manikins and associated devices, including for instance the head manikin 100, the torso manikin 200 and the defibrillation pads 240 described hereinbefore, the manikins and associated devices being indirectly connected to the server 362 through a computing device 312 and a network communication link. This step may be referred to as the practical evaluation step 440.

Steps 430 and 440 can generally correspond to the application of the method 500 described hereinafter.

Once the trainee has successfully completed the one or more practical evaluation, they may receive a certificate confirming the completion of the training program in a subsequent step 450. In some embodiments, the certificate can comprise a unique number, such that the validity of the certificate can be verified via a web page accessible on the server 362. In preferred embodiments, the unique number is embedded in a QR code printed on the certificate, the QR code being decodable to a URL of a web page accessible on the server 362 providing validation information for the certificate. Various other certificate generation methods can also be used.

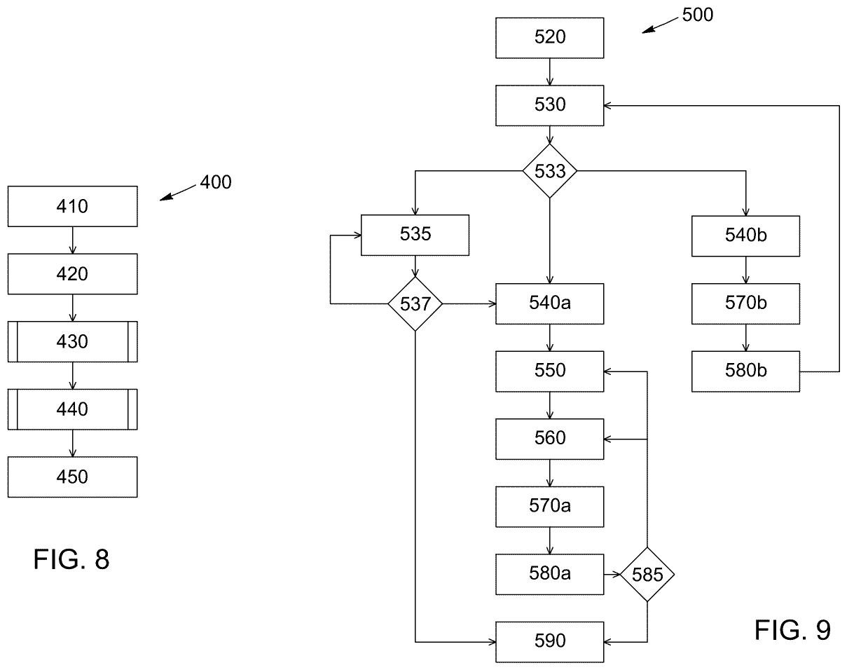

With reference to FIGS. 7 and 9, the training system 300 can be used for instance to perform a training or evaluation method 500. Broadly described, the method 500 makes it possible for a trainee to use one or more manikins and associated devices, including for instance the head manikin 100, the torso manikin 200 and defibrillation pads 240 described hereinbefore, to practise a complete life support, CPR and/or airway management program, and obtain feedback by comparing their performance with reference parameters 364.

It is appreciated that reference parameters 364 and the steps in the example method 500 can correspond to one of the life-support recommendations or guidelines established by organizations, including for instance the American Heart Association®, the Heart and Stroke® Foundation of Canada and the Canadian Red Cross, and therefore that the reference parameters 364 and the methods described herein can change from type of victim to type of victim, from time to time, from organization to organization and/or from region to region. These guidelines also provide the precise definition of the words “infant,” “child” and “adult.” As an example, an “infant” can be a human less than one year old, a “child” can be a prepubescent human at least one year old, and an “adult” can be a pubescent or postpubescent human. It is appreciated that the order of the steps described hereinbelow correspond to an arbitrarily chosen guideline, and that choosing a different guideline may result in a different step order and in certain steps being omitted. As an example, in certain guidelines for infants, step 550 is omitted, and steps 570a and 580a are performed before step 540a when there is only one first aid provider. It is also noted that the system 300 can include multiple training programs for respective certifications and jurisdictions, and the trainee can select which program is to be followed depending on the desired certification. For example, the trainee can select the training program required in a given jurisdiction (e.g., Canada) and the system 300 will then provide the required training program based on the requirements in the selected jurisdiction. It is also noted that since training guidelines may change in a given jurisdiction, the trainee having received certification based on certain guidelines may receive a notification that the guidelines have changed and thus further training is recommended based on updated guidelines.

As a first step 520, a trainee can activate the manikins 100 and 200 and defibrillation pads 240, for instance by the button 265 or by a functionality in the smartphone app 314. The manikins 100 and 200 can obtain, from the server 362, a scenario for the practice session, including for instance the age, the height, the weight, the lung volume and the chest resistance of the victim, whether the victim is pregnant, the duration of the practice session, and/or a specification of the state of the victim at the start of and throughout the session, e.g., whether the victim is breathing, has a pulse and/or is in a choking state at the start, and whether and when the victim stops breathing, has a pulse and/or is in a choking state. The scenario can be selected by the trainee or by a trainer, or can be selected automatically by the server 362 among a set of predetermined possible scenarios. If the victim has no pulse and has an age corresponding to an infant according to the recommendations in use, e.g., if the victim is less than 1-year-old, the trainee may place the torso manikin 200 on a rigid and flat surface, so that the infant surface 215 faces upwards. If the victim has no pulse and has an age that corresponds to a child or an adult according to the recommendations in use, e.g., if the victim is 1-year-old or more, the trainee may place the torso manikin 200 so that the adult surface 210 faces upwards. If the victim is choking, the trainee may place the torso manikin 200 in the appropriate position for airway obstruction treatment manoeuvres as described hereinafter in step 535.

Before the practice session starts, the actuator of the gate 149 of the variable flow valve 140 can move the gate 149 to the closed position. Moreover, before the practice session starts, the pump 251 can force a volume of air inside the inflatable pouch 201 sufficient to create a pressure corresponding to the chest resistance obtained from the server 362. As an example, in one embodiment, the inflatable pouch 201 contains a quantity of air sufficient such that a hand applying a pressure of 100 lbf will cause a depression of approximately 2 inches in the pouch 201 and that a hand applying a pressure of 125 lbf will cause a depression of approximately 2.4 inches.

As a next step 530, the trainee can perform an assessment of the state of the victim, including for instance the state of consciousness of the victim, whether the victim is breathing and/or whether the victim has a pulse. The trainee can be prompted to do so by the training system, e.g., via a sound alert to begin. The trainee can perform an assessment of the respiratory and cardiac state of the victim according to the recommendations taught, for instance by listening for breathing sounds, which can for instance be simulated or not by a speaker 190 in the head manikin 100, by visualizing whether the victim chest is rising as a result of breathing, which can for instance be simulated by the pump 251 forcing an additional quantity air in the chamber 205 to increase the volume of the inflatable pouch 201, and by checking for the presence of a carotid pulse, which can for instance be simulated or not by a vibrating device 279 in the torso manikin 200. As an example, assessing the state of consciousness of the victim can include shouting “Mister, Mister” and/or “Are you OK?”, and/or squeezing firmly a location corresponding to the trapezius of the torso manikin 200 to simulate a trapezius squeeze. In some embodiments, a microphone and/or or a sound pressure sensor can be used to register a sound pressure level and, responsive to the sound pressure level being above a configurable threshold, an assessment of consciousness parameter 321 can be attributed a value. As an example, the assessment of consciousness parameter 321 can be a Boolean variable, which is set to a value of “true” if the sound pressure level is above the threshold. The sound pressure level threshold can for instance be 90, 95 or 100 dB, or any level between such values, measured at a position on the head manikin 100 near the location of the ears in a human head. In some embodiments, an existing automatic speech recognition framework can be executed to convert the words spoken by the trainee to text and, responsive to the sound pressure level being above a configurable threshold and the spoken text corresponding to a configurable list of acceptable phrases, attribute to the assessment of consciousness parameter 321 a corresponding value. In some embodiments, the assessment of consciousness parameter 321 can be set to a value of “true” if, alternatively or additionally, the pressure sensor 257 registers a pressure increase above a configurable threshold corresponding to the trainee performing a trapezius squeeze manoeuvre. The pressure increase threshold can for instance correspond to 125%, 118% or 111% of the initial pressure, corresponding to the trainee performing a manoeuvre that reduces the volume of the chamber 205 to approximately 80%, 85% or 90% of its initial volume, or a level between such values. It is appreciated that some guidelines may provide that certain categories of first aiders e.g., professional first aiders, should reassess the state of the victim periodically throughout the first aid process, for instance by verifying whether the victim has a pulse every minute. Compliance with such guidelines can be include in the computation of the assessment of consciousness parameter 321.

As a next step 533, the trainee can be required to select the proper program corresponding to the assessed state of the victim. As an example, the victim may be choking, i.e., suffering from an airway obstruction, and may therefore be conscious, have a pulse, but be incapable of breathing. If this is the case, the next step may be the airway obstruction treatment step 535. As another example, the victim may be unconscious and have no pulse and no breathing, which may indicate that the victim is undergoing cardiac arrest. If this is the case, the next step may be the call-for-help step 540a, to be followed by the defibrillation step 550. As a final example, the victim may be unconscious, have a pulse but not be breathing, which may indicate that the victim is undergoing respiratory arrest but not cardiac arrest. If this is the case, the next step may be the call-for-help step 540b, to be followed by the airway opening 570b step. In some embodiments, when the victim is unconscious but is undergoing neither cardiac nor respiratory arrest, the trainee may place the victim in a recovery position, e.g., the semi-prone position, call for help, and reassess the state of the victim on a regular basis.

The next step may be step 535, step 540a or step 540b, as will be described in further detail below.

In step 535, the trainee can place the torso manikin 200 in a vertical position to apply thrust manoeuvres, also known as Heimlich manoeuvres, and/or back slaps on the victim. As an example, if the victim is a child or an adult of an average size, the trainee may position the victim's back against his abdomen and perform abdominal thrusts; if the victim is obese or pregnant, the trainee may position the victim's back against his chest and perform sternal thrusts; if the victim is a tall person, the trainee may position the victim's back against a wall and perform sternal thrusts; and if the victim is an infant, the trainee may position the victim's back against their arm and perform sternal thrusts. The gyroscope 273 can be used to ensure that the torso manikin 200 is being held in a generally vertical position during such steps, unless the guidelines call for a different position for certain types of victims e.g., infant victims, in which case the gyroscope 273 can be used to ensure that the torso manikin 200 is being held in a generally supine position. The pressure sensor 257 can be used to measure variations in pressure inside the chamber 205 while the trainee is applying thrusts and attribute a value to a thrust force parameter 347. It is appreciated that different types of victims require a different thrust force. The optimal force is defined in the reference parameters 364 and, as with other steps, assessment of the trainee's performance is measured by comparing the thrust force parameter 347 to the reference parameters 364. In certain guidelines, a specified number of thrusts may alternate with a specified number of back slaps. For instance, in accordance with certain guidelines, the trainee may start by applying five abdominal thrusts on an infant victim, then turn the victim around so that the chest lies against the trainee's arm and apply five back slaps. In these cases, the pressure sensor 257 can additionally be used to measure variations in pressure inside the chamber 205 while the trainee is applying back slaps and attribute a value to a slap force parameter 349, and the gyroscope 273 can be used to ensure that the torso manikin 200 is being held in a generally prone position. It is appreciated that different types of victims require different slap forces, and that the appropriate thrust force is not necessarily equal to the appropriate slap force for a given victim.

As a next step 537, based on the scenario selected during the initialization step 520 and/or on the trainee's performance during the airway obstruction treatment step 535, the server 362, the computing device 312 or the torso manikin 200 can determine a subsequent stage in the scenario. As an example, the victim's airway may be successfully cleared, which can be for instance be simulated by the speaker 190 or 277 emitting coughing and spontaneous breathing sounds and/or by the air pump 251 forcing a volume of air inside the chamber 205 to simulate spontaneous breathing, in which case the training session can end and the following step is the feedback step 590. As another example, the victim's airway may still not be cleared and the victim may become unconscious, requiring the trainee to lay down the torso manikin 200 horizontally in order to begin a complete CPR sequence at step 540a. As another example, the victim's airway may still not be cleared and the victim may remain conscious, requiring the trainee to continue with the airway obstruction treatment step 535.

In step 540a or 540b, the trainee can call for help, for instance by shouting for help, by simulating a call to an emergency telephone number, e.g., 9-1-1, or calling out a code. Moreover, the trainee can request that a bystander obtain an AED. In embodiments using a microphone or a sound pressure sensor to measure a sound pressure level, responsive to the sound pressure level being above a configurable threshold over a configurable duration, a call-for-help parameter 323 can be attributed a value. As an example, the call-for-help parameter 323 can be a Boolean variable, which is set to a value of “true” if the sound pressure level is above the threshold over a given duration. In embodiments executing an automatic speech recognition framework, the spoken text can alternatively or additionally be compared to a configurable list of acceptable phrases to attribute to the call-for-help parameter 323 a corresponding value. In these embodiments, as an example, the call-for-help parameter 323 could be a vector of Boolean values, including for instance values to shouting for help, calling an emergency phone number, calling out a code and/or asking for an AED. The step following step 540a may be step 550, and the step following step 540b may be step 570b, as illustrated.

In step 550, the trainee can apply defibrillation pads 240 to the torso manikin 200. As an example, a correct position of the pads 240 can be defined as one pad 240 over magnet 220a and one pad 240 over magnet 220b for an adult, the proximal face of both magnets 220a and 220b having the same polarity; or one pad 240 over magnet 220c and one pad 240 over magnet 220d for a child, the proximal face of both magnets 220c and 220d having the same polarity which is different from the polarity of the proximal face of magnets 220a and 220b. The magnetic field sensors 243 in the pads 240 can be used to determine whether a measurable magnetic force is present and whether the magnetic field has the expected polarity in order to attribute a value to a pad positioning parameter 325. As an example, the pad positioning parameter 325 can be a pair of two categorical variables, each variable corresponding to one pad 240, each variable having a value of “over the correct magnet,” “over the wrong magnet” or “not over a magnet.” In some embodiments, once the trainee has applied the defibrillation pads 240, it can be determined, for instance by the smartphone app 314 applying a random function, whether a shock is to be simulated. If this is the case, a pre-recorded message can be played, for instance by a speaker installed in the computing device 312. As an example, the pre-recorded message can state, “Stand by, preparing to shock, everyone clear, do not touch the patient.” It is appreciated that the pre-recorded message can alternatively or additionally be played by a speaker installed in the head manikin 100 or the torso manikin 200. At that time, the trainee can shout for bystanders to stand clear. In embodiments using a microphone or a sound pressure sensor to measure a sound pressure level, responsive to the sound pressure level being above a configurable threshold over a configurable duration, a shock warning parameter 327 can be attributed a value. As an example, the shock warning parameter 327 can be a Boolean variable, which is set to a value of “true” if the sound pressure level is above the threshold over the duration. In embodiments executing an automatic speech recognition framework, the spoken text can alternatively or additionally be compared to a configurable list of acceptable phrases to attribute to the shock warning parameter 327 a corresponding value.

As a next step 560, the trainee can apply chest compressions to the torso manikin 200. The pressure sensor 257 can be used to measure variations in pressure inside the chamber 205 while the trainee is applying compressions, for instance by creating a curve having a substantially sinusoid appearance representing pressure as a function of time. The curve can be analyzed by the controller 263 in order to compute a compression depth parameter 329, an inter-compression relaxation parameter 331, a compression frequency parameter 333 and a compression count parameter 335. The compression depth parameter 329 can be proportional to the pressures measured at the curve maxima through the application of Boyle-Mariotte law. The inter-compression relaxation parameter 331 can represent the difference between the pressures measures at the curve minima and the initial pressure. As an example, certain recommendations suggest that the inter-compression relaxation parameter 331 computed in that manner should optimally have a value of zero, with tolerance for a value between zero and 10% of the initial pressure. The compression frequency parameter 333 can be inversely proportional to the average of the time elapsed between each pair of proximal maxima. As an example, certain recommendations suggest that chest compressions should have a frequency between 100 and 120 per minute, representing an average of 0.5 to 0.6 seconds between each pair of proximal maxima. The compression count parameter 335 represents the count of compressions performed by the trainee, e.g., the count of maxima on the curve, before the trainee moves to a different type of manoeuvre. As an example, certain recommendations suggest that a lone first aider should perform thirty chest compressions before performing the ventilation steps 570a and 580a.

As a next step 570a or 570b, the trainee can ensure the opening of the victim's airways, for instance by performing a head tilt manoeuvre and/or a jaw thrust manoeuvre. The tilt sensor 160 and the jaw position sensor 165 described hereinbefore can be used to determine whether the head is tilted and/or the lower jaw is subluxated, and attribute a value to an airway clearance parameter 337. As an example, the airway clearance parameter 337 can be a Boolean variable that is “true” when the head is tilted and/or the lower jaw is subluxated. Moreover, responsive to the head being tilted and/or the lower jaw being subluxated, the actuator of the gate 149 of the variable flow valve 140 can move the gate 149 to the open position to simulate the victim's airway being cleared. If the head and lower jaw move back to their natural position, the actuator of the gate 149 of the variable flow valve 140 can move the gate 149 back to the closed position to simulate the victim's airway being blocked by their tongue. In some embodiments, the tilt sensor 160 and/or the jaw position sensor 165 can have a reading corresponding to a continuous value rather than a Boolean value. In these embodiments, the airway clearance parameter 337 can for instance be a real variable having a value of 0 when the head is nor tilted and the lower jaw is not subluxated, of 1 when the head is sufficiently tilted or the lower jaw is sufficiently subluxated, and of between 0 and 1 in other cases. In these embodiments, responsive to the real airway clearance parameter 337 between above 0 and below 1, the actuator of the gate 149 of the variable flow valve 140 can move the gate 149 to the partially open position to simulate the victim's airway being partially cleared.

As a next step 580a or 580b, the trainee can perform insufflation. It can be appreciated that insufflation can be performed by any technique, including for instance mouth-to-mouth, mouth-to-mask, mouth-to-nose, mouth-to-mouth and nose, a mechanical ventilation tool such as a bag valve mask, and a passive ventilation tool such as an Oxylator® or a CAREVent® used in manual mode. The pressure sensor 130 and/or the flow sensor 150 can be used to measure an insufflation volume and compute therefrom an insufflation volume parameter 339. When the victim's airway is cleared and the insufflation volume is zero, the gate 149 of the variable flow valve can remain in the open position. As the insufflation volume rises, the actuator of the gate 149 can move the gate to a progressively less open position, following a function GatePosition=k·V÷Vₘₐₓ, where GatePosition is as defined hereinbefore, 0 indicating an open gate 149 and 1 indicating a closed gate 149, k is a constant factor, for instance 0.85, 0.9 or 0.95, ensuring that the gate 149 does not become completely closed, V is the insufflated volume, and Vₘₐₓ is the optimal insufflation volume according to certain recommendation, for instance between 500 mL and 750 mL for adults. As an example, if k is 0.9, if the optimal insufflation volume is 600 mL and 3331/3 mL of air have been insufflated, the gate 149 is in position 0.5 and the variable flow valve is limiting the flow rate to 50% of the nominal flow rate. This can have the effect of increasing the pressure in the part of the channel 120 that is upstream from the variable flow valve 140, in order to let the trainee feel that the victim's lungs are filling up. In some embodiments, as the insufflation volume rises, the pump 251 can force an additional quantity air in the chamber 205 to increase the volume of the inflatable pouch 201, in order to simulate the victim's chest rising responsive to their lung filling up. In these embodiments, enough air can be forced in the chamber 205 by the pump 251 for the pressure sensor 257 to register an increase ΔP=kV/Vₘₐₓ, where k is a constant factor, V is the insufflated volume and Vₘₐₓ is the optimal insufflation volume. As soon as the flow sensor 150 registers a flow rate of zero, solenoid valve 256 can let the additional air out. It can be appreciated, as explained hereinbefore, that the functions just described for the flow sensor 150 can alternatively or additionally be performed by computations of the readings of the pressure sensor 130 by the processor 180. The pressure sensor 130 can be used to determine a value for an insufflation force parameter 341. The insufflation force parameter 341 can correspond to the increase in the channel 120 pressure measured by the pressure sensor 130 over a short period of time, for instance 0.1 seconds. If the force insufflation force parameter 341 is elevated, corresponding for instance to a pressure above 35 cmH₂O in channel 120, there is a risk of causing emesis or barotrauma in the victim. As an example, in embodiments using a speaker, when the force insufflation force parameter 341 is elevated, emesis sounds can be produced to provide immediate feedback to the trainee. The pressure sensor 130 and/or the flow sensor 150 can also be used to determine the value of an insufflation duration parameter 343 and of an insufflation count parameter 345. As an example, in ventilation step 580a for victims undergoing cardia arrest, certain recommendations suggest that a lone first aider should perform two insufflations, each lasting 1 to 1.5 s and separated by a 1 to 1.5 s pause before attending to chest compressions once more before more than 10 s have elapsed in total. As a further example, in ventilation step 580b for victims undergoing respiratory arrest but not cardiac arrest, certain recommendations suggest that a first aider should perform one insufflation every 6 seconds during one minute before reassessing the cardiac state of the victim in step 530.

Following step 580a, as a next step, 585, it can be necessary to determine whether the practice session has exceeded its duration and is finished, or whether it continues. If it continues, the next step 560 can comprise the trainee applying chest compressions again. After a certain amount of time has elapsed since applying the defibrillation pads 240 to the torso manikin 200, for instance 2 minutes, the next step 550 can comprise the DEA reassessing the victim again and deciding again whether a shock is to be simulated.

The last step 590 after the practice session has ended can comprise the trainee receiving feedback, for instance through the smartphone app 314. As an example, the server 362 can compare the parameters 320 computed throughout the execution of the method 500 and compare them with the reference parameters 364 that correspond to the recommendations the trainee was taught. The smartphone app 314 is then capable of providing the trainee for instance with a detailed analysis of the errors that were made and with a progression report comparing the trainee's performance across a plurality of practice sessions. If the practice session corresponds to a practical evaluation 440, the server 362 can attribute a score inversely proportional to the distance between the computed parameters 320 and the reference parameters 364.

It is appreciated that the reference parameters 364 can be computed in different ways. As one example, the reference parameters 364 can be the result of theoretical calculations in regard of reference guidelines e.g., calculating, in view of the volume and initial fluid pressure in the chamber 205, the range of modified fluid pressures corresponding to a compression of a depth between 2 and 2.4 inches. As another example, the reference parameters 364 can be the result of method 500 being performed by one or more expert First Aid practitioner, one or more time, according to one or more scenario and in observance of specific reference guidelines, computing parameters 320, and using an aggregation of computed parameters 320 as reference parameters 364. The aggregation can for instance comprise the average or median of each computed parameter 320, the maximum and minimum value of each computed parameter 320, or the lower and upper bounds of a confidence interval e.g., a 95% confidence interval, of each computed parameter 320.

As can be appreciated, the above-described systems and methods can facilitate several advantages that can facilitate versatile, autonomous and cloud-based First Aid, CPR, airway management and ventilation training using hygienic, environment-friendly, lightweight and economical manikins. The combination of a universal head manikin and inflatable torso manikin usable to simulate CPR, airway management and ventilation on infants, children and adults alike makes for a transportable and economical CPR, airway management and ventilation training set. Along with many innovations disclosed herein to automatize the assessment of the trainee's performance, such as using sensors to detect speech by the trainee, jaw subluxation and defibrillation pad placements, this facilitates offering distance CPR, airway management and ventilation training. Since a variety of parameters are computed and compared automatically with reference parameters, it is relatively simple to keep the training and assessment up to date with the latest local recommendations. The innovative variable flow valve in the head manikin disclosed herein and the air pump in the torso manikin together facilitate the benefits of lung bags, such as allowing the trainee to see a manikin's chest rise during insufflation, without certain drawbacks. For instance, in some embodiments, no parts in the disclosed manikins need to be changed between trainees or between classes, which helps cutting costs and preserving the environment. Nonetheless, because the variable flow valve facilitates the trainee being able to obtain the same feedback as with lung bags while redirecting filtered insufflated air in a safe direction, embodiments of the disclosed manikins are more hygienic and can be safely used to practise techniques such as mouth-to-mouth even in contexts such as the Covid-19 pandemic. The variable flow valve-air pump combination, moreover, facilitates simulating practising on patients of various morphologies, including for instance various lung capacities and levels of chest resistance, without having to use a different manikin.

Numerous specific details have been set forth in order to provide a thorough understanding of the example embodiments described herein. However, it will be understood by those of ordinary skill in the art that the embodiments described herein may be practised without these specific details. In other instances, well-known methods, procedures and components have not been described in detail so as not to obscure the embodiments described herein. Furthermore, this description is not to be considered as limiting the scope of the embodiments described herein in any way but rather as merely describing the implementation of the various embodiments described herein.

1. A first aid manikin, comprising:
a head comprising:
an outer shell defining an inner chamber;
an inlet on a front surface of the outer shell;
an outlet on the outer shell, the outlet being distinct from the inlet;
a channel within the inner chamber, the channel allowing fluid communication between the inlet and the outlet;
at least one sensor configured to generate sensor data related to head position and/or fluid flow through the channel; and
a variable flow valve located in line with the channel, the variable flow valve being configured to vary a fluid flow in the channel based on the sensor data.

2. The manikin according to claim 1, the head further comprising a one-way valve located in line with the channel and configured to allow fluid flow from the inlet towards the outlet and to block fluid flow towards the inlet.

3-9. (canceled)

10. The manikin according to claim 1, the head further comprising a communication device configured to receive the sensor data, and to receive and send information to a computing device.

11. (canceled)

12. The manikin according to claim 1, the head further comprising a tilt sensor attached to a rear part of the outer shell, wherein the sensor data comprises readings from the tilt sensor.

13. The manikin according to claim 11, the head further comprising a jaw position sensor located in the inner chamber, wherein the sensor data comprises readings from the jaw position sensor.

14. The manikin according to claim 1, wherein the channel comprises an upstream tube extending from a mouth of the head to the one-way valve, an intermediate tube extending from the one-way valve to the variable flow valve, and a downstream tube extending from the variable flow valve to the outlet.

15-23. (canceled)

24. The manikin according to claim 1, wherein the head is operably couplable to a torso.

25-73. (canceled)

74. The manikin according to claim 24, wherein the torso comprises:
an inflatable pouch, the pouch comprising a flexible wall defining an interior chamber; and
a torso fluid pressure sensor configured to detect compressions being applied to the pouch.

75. The manikin according to claim 74, the pouch further comprising an adult simulation surface on a first side and an infant simulation surface on a second side, in opposed relation to the adult simulation surface.

76. The manikin according to claim 74, wherein the torso fluid pressure sensor is further configured to detect squeezing being applied to the pouch.

77. The manikin according to claim 74, the torso further comprising an air pump configured to inflate the pouch by forcing air in through an air intake vent.

78. The manikin according to claim 74, the torso further comprising an air exhaust vent configured to deflate the pouch.

79. The manikin according to claim 74, the pouch further comprising at least two magnets, each magnet being attached to and underneath a surface of the pouch.

80. The manikin according to claim 79, further comprising at least two defibrillation pads, each pad being configured to adhere to a surface of the pouch when applied to said surface, each pad comprising a magnetic field sensor.

81. The manikin according to claim 1, the head further comprising a fluid pressure sensor located in the channel, wherein the sensor data comprises readings from the fluid pressure sensor.

82. The manikin according to claim 1, the head further comprising a flow sensor located in the channel, wherein the sensor data comprises readings from the flow sensor.

83. A variable flow valve for use in the manikin of claim 1, the variable flow valve being positionable in line with a channel that provides fluid communication between an inlet and an outlet of a head of the manikin, the variable flow valve comprising:
a housing having an inner cavity;
an intake provided in the housing;
an exhaust provided in the housing and being distal from and in fluid communication with the intake;
a gate located within the cavity and being movable between:
an open position allowing fluid communication from the intake to the exhaust, a plurality of partially open positions allowing restricted flow fluid communication from the intake to the exhaust, and
a closed position blocking fluid communication from the intake to the exhaust; and
an actuator configured to move the gate between the open position, the plurality of partially open positions, and the closed position, in response to readings obtained from at least one sensor located on the manikin and generated in response to a user performing first aid manoeuvres on the manikin.

84. The variable flow valve according to claim 83, wherein the housing is configured such that the inner cavity has an upstream region with an outward taper and a downstream region that accommodates the gate and includes the exhaust.

85. The variable flow valve according to claim 84, wherein the downstream region has a spherical shape and the gate has an outer spherical surface that cooperates with inner surfaces of the downstream region to slide thereon.

86. A first aid training method, comprising:
generating data from a user manipulating a first aid manikin, the manikin comprising a head and a torso, the head comprising at least:
a channel that provides fluid communication between an inlet and an outlet of the head,
a plurality of sensors configured to generate sensor data related to at least one of head position and fluid flow through the channel,
a variable flow valve located in line with the channel, and
a controller configured to receive the sensor data and to send information comprising at least the sensor data to a computing device; and
in the computing device:
receiving the information,
comparing the information with first aid reference parameters stored in the computing device, and
displaying feedback to the user based on comparison of the information with the first aid training parameters.
